(19) United States
(12) Patent Application Publication
(10) Pub. No.: US 2013/0001758 A1
(43) Pub. Date: Jan. 3, 2013

(54) Power Semiconductor Package

(75) Inventors: Thomas Joachim Werner MOERSHEIM, Taguig (PH); Fernando Villon CAPINIG, Taguig (PH); Dandy Navarro JADUCANA, Taguig (PH); Anthony Augusto Malon GALAY, Taguig (PH)

(73) Assignee: PSI Technologies, Inc., Taguig (PH)

(21) Appl. No.: 13/609,205

(22) Filed: Sep. 10, 2012

Related U.S. Application Data
(63) Continuation-in-part of application No. 13/288,979, filed on Nov. 4, 2011.
(60) Provisional application No. 61/426,497, filed on Dec. 22, 2010.
(60) Provisional application No. 61/452,632, filed on Mar. 14, 2011.

(51) Int. Cl. H01L 23/495

(52) U.S. Cl. 257/675; 257/E23.051

(57) ABSTRACT

The present invention provides a power semiconductor package. The power semiconductor package comprises a dual lead frame assembly comprising a bottom lead frame having a first heat sink pad at its bottom surface and a top lead frame having a second heat sink pad at its bottom surface. The top lead frame is coupled to the bottom lead frame by an isolation layer, wherein the isolation layer is a thermal conductive, but electrical isolative, material. The power semiconductor package further comprises a power semiconductor device coupled to the top lead frame of the dual lead frame assembly and an encapsulation member encapsulating the dual lead frame assembly and the power semiconductor device, while exposing the first heat sink pad at the bottom surface of the bottom lead frame.

### CROSS-REFERENCE TO RELATED APPLICATIONS

This application is a continuation-in-part, and claims the benefit of U.S. patent application Ser. No. 13/288,979 filed on Nov. 4, 2011 and entitled “Scalable Heat Dissipating Microelectronic Integration Platform (SHDMIP) for Lighting Solutions and Method for Manufacturing Thereof”, which claims the benefit of U.S. Provisional Patent Application No. 61/426,497 filed on 22 Dec. 2010 and U.S. Provisional Application No. 61/452,632 filed on 14 Mar. 2011, the entireties of which are incorporated herein by reference.

### FIELD OF THE INVENTION

The present invention in general relates to semiconductor devices. In particular, the present invention relates to electrically isolated power semiconductor package.

### BACKGROUND

Power semiconductor package such as transistors, thyristor, insulated gate bipolar transistor (IGBT), and the like is operable at high-voltage operation ranging from 30V to 1000, or even higher. The operation of the power semiconductor package generates substantial amount of waste heat that needs to be dissipated out, or else package damage might occur due to overheating. To dissipate the waste heat, the power semiconductor package can be coupled to an external heat sink.

In many applications, it is required to electrically isolate the semiconductor components of the power semiconductor package from the external heat sink. Currently, there are several methods are known to electrically isolate the power semiconductor package. These known isolation process require either plastic foil, thermal grease or non conductive heat sink made of ceramics as isolating materials. The use of ceramics or plastics for isolation of power semiconductor package has several disadvantages such as expensive manufacturing cost, significant thermal impedance, and difficulties during handling.

Full pack power semiconductor package offers an alternative to the standard power semiconductor package that it has heat sink encapsulated therein. Thus, it does not require any external heat sink for waste heat dissipation. Current full pack power semiconductor packages are being electrically isolated by transfer molding compound process.

Electrical isolation process of the full pack power semiconductor package by transfer molding process is a costly manufacturing process with relatively low yield and reliability. The set-up cost of the molding equipments is high and the regular maintenance cost of the same is not cheap either. Regular maintenance of the equipments is unavoidable since it purposes to guarantee the isolation properties of the full pack power semiconductor package.

The isolation materials used during transfer molding process can be epoxy material. When the transfer molding epoxy material is used as isolation materials, it is very typical to find micro voids in the final product. The micro voids can cause electrical failure. Another problem with the epoxy material is that only a considerably small isolation layer of the epoxy can be applied to the power semiconductor package. Small isolation layer is not preferable for power semiconductor package as it may misplace lead frame of the full pack power semiconductor package during encapsulation process, causing short circuit in high voltage applications. Therefore, the use of epoxy as isolation material are highly dangerous, especially in high voltage applications or applications to medical devices.

An alternative to the use of epoxy material as isolation materials in transfer molding process is ceramics. However, ceramics are considerably expensive, especially high voltage suitable ceramics. Further, ceramic is an inferior thermal conductor, makes it not very suitable for most electrical applications.

### SUMMARY

In one aspect of the present invention, there is provided a power semiconductor package. The power semiconductor package comprises a dual lead frame assembly comprising a bottom lead frame having a first heat sink pad at its bottom surface and a top lead frame having a second heat sink pad at its bottom surface. The top lead frame is coupled to the bottom lead frame by an isolation layer. The isolation layer is a thermally conductive, but electrically isolative, material. The power semiconductor package further comprises a power semiconductor device coupled to the top lead frame of the dual lead frame assembly and an encapsulation member encapsulating the dual lead frame assembly and the power semiconductor device, while exposing the first heat sink pad at the bottom surface of the bottom lead frame.

In one embodiment of the present invention, the isolation layer can be selected from a group of standard thermal paste material.

In another embodiment of the present invention, the isolation layer can be selected from a group of special thermal conductive material such as sinter glue.

In another further embodiment of the present invention, the isolation layer can be selected from a group of pre-formed thermal conductive material.

In yet another further embodiment of the present invention, the isolation layer between the top and bottom lead frame is applied using a screen-printing methodology.

In one embodiment of the present invention, the isolation layer is applied using a standard dispensing process.

In another embodiment of the present invention, the isolation layer between the top and bottom lead frame is applied using a pick and place process.

In one specific embodiment of the present invention, the thickness of the isolation layer is 254 μm.

In one embodiment of the present invention, the dual lead frame assembly is made of copper. The top lead frame may further comprise a plurality of metal areas for external connection purpose.

### BRIEF DESCRIPTION OF THE DRAWINGS

This invention will be described by way of non-limiting embodiments of the present invention, with reference to the accompanying drawings, in which:

FIG. 1 illustrates an exploded view of a power semiconductor package in accordance with one embodiment of the present invention; and

FIG. 2 illustrates a schematic diagram the power semiconductor package of FIG. 1 in upside-down position.

### DETAILED DESCRIPTION

The following descriptions of a number of specific and alternative embodiments are provided to understand the inventive features of the present invention. It shall be apparent to one skilled in the art, however that this invention may be practiced without such specific details. Some of the details may not be described in length so as to not obscure the invention. For ease of reference, common reference numerals will be used throughout the figures when referring to same or similar features common to the figures.

The present invention provides a reliable power semiconductor package. The power semiconductor package of the present invention is manufactured at an acceptable cost with high electrical and mechanical reliability.

The power semiconductor package of the present invention uses an isolation layer between two metal carriers to form a fully isolated power semiconductor package. The two metal carriers may be in a form of lead frame assembly or clip assembly

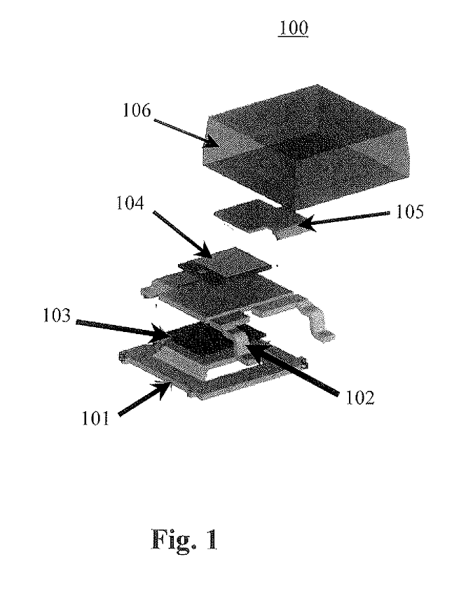

FIG. 1 illustrates an exploded view of power semiconductor package 100 according to one embodiment of the present invention. In this embodiment, the power semiconductor package 100 is particularly useful for packaging power MOSFET devices. Typically, MOSFET devices have large current capabilities, which could generate significant heat.

In another embodiments, the power semiconductor package 100 may also be used for packaging any other semiconductor dies, such as transistors, IGBT, thyristor, and the like.

Referring again to FIG. 1, the power semiconductor package 100 comprises a dual lead frame assembly. The dual lead frame assembly comprises a bottom lead frame 101 having a first heat sink pad (not shown) and a top lead frame 102 having a second heat sink pad (not shown). The first and second heat sink pads are disposed at bottom surface of the bottom lead frame 101 and top lead frame 102, respectively.

It is preferable that the dual lead frame is made of Copper. Copper is a superior thermal conductor as compared to other materials.

The top lead frame 102 is coupled to the bottom lead frame 101 by an isolation layer 103. The isolation layer 103 is a thermally conductive, yet electrically isolative, material. The isolation layer 103 isolates the power semiconductor package 100 as well as allows the power semiconductor package 100 to have precise electrical and thermal characteristics as desired. Some of thermal characteristics desired for the power semiconductor package 100 includes thermal resistance in the range of 3-4° C./watt and isolation voltage capability in the range of 2.5-5 kV.

The thickness of the isolation layer 103 can be adjusted in accordance with energy demand of the power semiconductor package 100. When the power semiconductor package 100 demands a higher energy, thicker isolation layer 103 is applied in between the top lead frame 102 and the bottom lead frame 101.

In one embodiment, the thickness of the isolation material is about 254 μm. The isolation capability of power semiconductor package having 254 μm thick isolation material is about 5 kV with a thermal resistance of 7° C./watt.

The isolation layer can be applied by many ways known in the art, such as by high precision screen-printing methodology. The isolation layer can also be pre-formed and simultaneously dispensed by a standard dispensing process or a pick and place process.

In one embodiment, the isolation layer may be thermal paste material, special thermal conductive material, such as Heraeus sinter glue, or pre-formed thermal conductive material.

Still referring to FIG. 1, a power semiconductor device 104 is electrically coupled to the top lead frame 102. The top lead frame 102 thus provides a drain electrode to the power semiconductor devices 104. The power semiconductor device 104 may be a MOSFET device. Solder or any type of adhesive material may be used to couple the power semiconductor devices to the top lead frame. A copper clip 105 connects upper portion of the power semiconductor device 104 to the top lead frame 102.

Power semiconductor device 104 may be further electrically connected to a plurality of metal areas provided in the top lead frame 102. This connection is to provide source and gate electrode to the power semiconductor device 104. In one embodiment, the electrical connection may be established by using gold or copper wirebond. The plurality of metal areas provided in the top lead frame 102 is also adapted to provide an external electrical connection between the power semiconductor package 100 to an external circuit.

After electrical connecting process of the power semiconductor device 104 is achieved, an encapsulation member 106 is provided to form a fully electrical isolated power semiconductor package 100. The encapsulation member 106 encapsulates the power semiconductor device 104 and the dual lead frame assembly, while the heat sink at bottom surface of the bottom lead frame 101 is exposed through the encapsulation member 106.

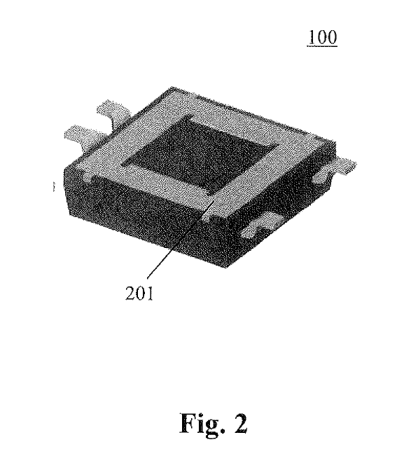

FIG. 2 illustrates a schematic diagram of the power semiconductor package 100 in upside-down position. The first heat sink pad 201 at bottom surface of the bottom lead frame 101 is exposed. The exposed heat sink 201 is isolated through. the isolation layer of thermally conductive yet electrically isolative material.

Still referring to FIG. 2, the exposed heat sink 201 allows the power semiconductor package to be attached to external heat sinks for waste heat dissipation. This adds advantages to lowering manufacturing cost and heat waste dissipation properties of the power semiconductor package of the present invention as compared to existing full-pack power semiconductor packages. The power semiconductor package of the present invention also has similar isolation voltage and thermal resistance properties as that of the full-pack power semiconductor packages.

The power semiconductor package of the present invention offers several advantages. The manufacturing process of the power semiconductor package adopts standard methodologies and does not require expensive equipments. The power semiconductor package has good reliability too as the waste heat can be effectively dissipated, thus increasing life expectation of the power semiconductor package. With these characteristics, the power semiconductor package can be used safely in wide range of applications, even in medical devices, automotive and any high voltage applications.

The above description illustrates various embodiments of the present invention along with examples of how aspects of the present invention may be implemented. While specific embodiments have been described and illustrated it is understood that many charges, modifications, variations and combinations thereof could be made to the present invention without departing from the scope of the present invention. The above examples, embodiments, instructions semantics, and drawings should not be deemed to be the only embodiments, and are presented to illustrate the flexibility and advantages of the present invention as defined by the following claims:

1. A power semiconductor package comprising:
a dual lead frame assembly comprising a bottom lead frame having a first heat sink pad at its bottom surface and a top lead frame having a second heat sink pad at its bottom surface, the top lead frame is coupled to the bottom lead frame by an isolation layer, wherein the isolation layer is a thermally conductive, but electrically isolative, material;
a power semiconductor device coupled to the top lead frame of the dual lead frame assembly; and
an encapsulation member encapsulating the dual lead frame assembly and the power semiconductor device and exposing the first heat sink pad at the bottom surface of the bottom lead frame.

2. The power semiconductor package of claim 1, wherein the isolation layer can be selected from a group of standard thermal paste material.

3. The power semiconductor package of claim 1, wherein the isolation layer can be selected from a group of special thermal conductive material such as sinter glue.

4. The power semiconductor package of claim 1, wherein the isolation layer can be selected from a group of pre-formed thermal conductive material.

5. The power semiconductor package of claim 1, wherein the isolation layer between the top and bottom lead frame is applied using a screen-printing methodology.

6. The power semiconductor package of claim 1, wherein the isolation layer between the top and bottom lead frame is applied using a standard dispensing process.

7. The power semiconductor package of claim 1, wherein the isolation layer between the top and bottom lead frame is applied using a pick and place process.

8. The power semiconductor package of claim 1, wherein the dual lead frame assembly is made of copper.

9. The power semiconductor package of claim 1, wherein the top lead frame further comprises a plurality of metal areas for external connection purpose.

10. The power semiconductor package of claim 1, wherein the thickness of the isolation layer is 254 μm.
